(19) United States
(12) Patent Application Publication
(10) Pub. No.: US 2014/0055013 A1
(43) Pub. Date: Feb. 27, 2014

(54) METHOD FOR MANUFACTURING CASING AND CASING OF PORTABLE ELECTRONIC DEVICE

(71) Applicant: Wistron Corporation, New Taipei City (TW)

(72) Inventors: Chi-Hen Lee, New Taipei City (TW); Chien-Wei Chen, New Taipei City (TW)

(21) Appl. No.: 13/937,219

(22) Filed: Jul. 9, 2013

(30) Foreign Application Priority Data
Aug. 24, 2012 (CN) 201210307206.X

(51) Int. Cl. H05K 5/02; B29D 99/00

(52) U.S. Cl. CPC H05K 5/02; B29D 99/006
USPC 312/223.1; 156/245

(57) ABSTRACT

A method for manufacturing a casing includes steps of providing a film; attaching a strengthening plate onto the film; placing the film and the strengthening plate into a mold; and injecting a plastic material into the mold such that the plastic material and the strengthening plate are combined with each other.

### BACKGROUND OF THE INVENTION

1. Field of the Invention

The invention relates to a method for manufacturing a casing and, more particularly, to a casing of a portable electronic device and a method for manufacturing the same.

2. Description of the Prior Art

So far casings of various portable electronic devices (e.g. notebook, tablet personal computer, etc.) are manufactured by injection molding. To strengthen the casing, a strengthening member (e.g. iron member) maybe placed into a mold first and then a plastic material is injected into the mold such that the plastic material and the strengthening member are combined with each other by insert molding. After the plastic material and the strengthening member are combined with each other, an outer surface always has a drop height (e.g. gap or overflowed material) such that a manufacturer must process the outer surface with additional surface treatment (e.g. spackle or grinding by abrasive paper) first and then the manufacturer can spray paint on the outer surface or process the outer surface with other appearance treatments. The aforesaid surface treatment always takes lots of labor and time such that the manufacture cost is increased.

### SUMMARY OF THE INVENTION

The invention provides a method for manufacturing a casing and a casing of a portable electronic device so as to solve the aforesaid problems.

According to an embodiment of the invention, a method for manufacturing a casing comprises steps of providing a film; attaching a strengthening plate onto the film; placing the film and the strengthening plate into a mold; and injecting a plastic material into the mold such that the plastic material and the strengthening plate are combined with each other.

In this embodiment, the method of the invention may further comprise step of cutting an edge of the film.

In this embodiment, the method of the invention may further comprise steps of removing the film and spraying paint on surfaces of the plastic material and the strengthening plate.

According to another embodiment of the invention, a casing of a portable electronic device comprises a film, a strengthening plate and a plastic material. The film has a recess. The strengthening plate is disposed in the recess. The plastic material is disposed in the recess and combined with the strengthening plate.

As mentioned in the above, the invention attaches the strengthening plate onto the film first, places the film and the strengthening plate into the mold together, and then injects the plastic material into the mold such that the plastic material and the strengthening plate are combined with each other. After insert molding, the film can prevent a drop height between an outer surface of the plastic material and the strengthening plate effectively since the film is attached on the outer surface of the plastic material and the strengthening plate. In other words, after manufacturing the casing of the portable electronic device of the invention by insert molding, the invention does not need additional surface treatment (e.g. grinding by abrasive paper). Therefore, the invention can save lots of labor and time from surface treatment so as to reduce the manufacture cost.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating a portable electronic device according to an embodiment of the invention.

FIG. 2 is a flowchart illustrating a method for manufacturing a casing according to an embodiment of the invention.

FIG. 3 is a schematic diagram illustrating processes for FIG. 1.

FIG. 4 is a top view illustrating the strengthening plate shown in FIG. 3.

FIG. 5 is a top view illustrating a film according to another embodiment of the invention.

FIG. 6 is a schematic diagram illustrating a portable electronic device according to another embodiment of the invention.

### DETAILED DESCRIPTION

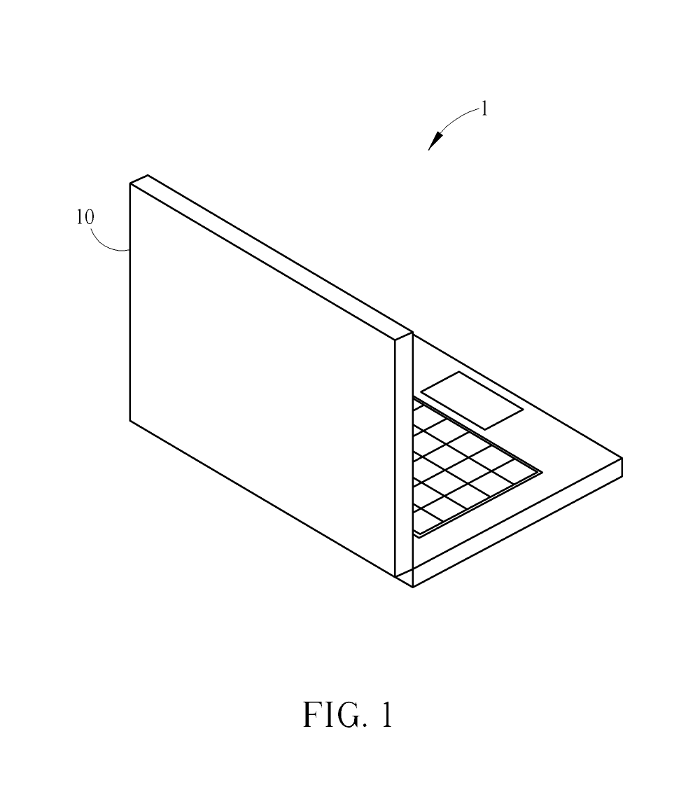

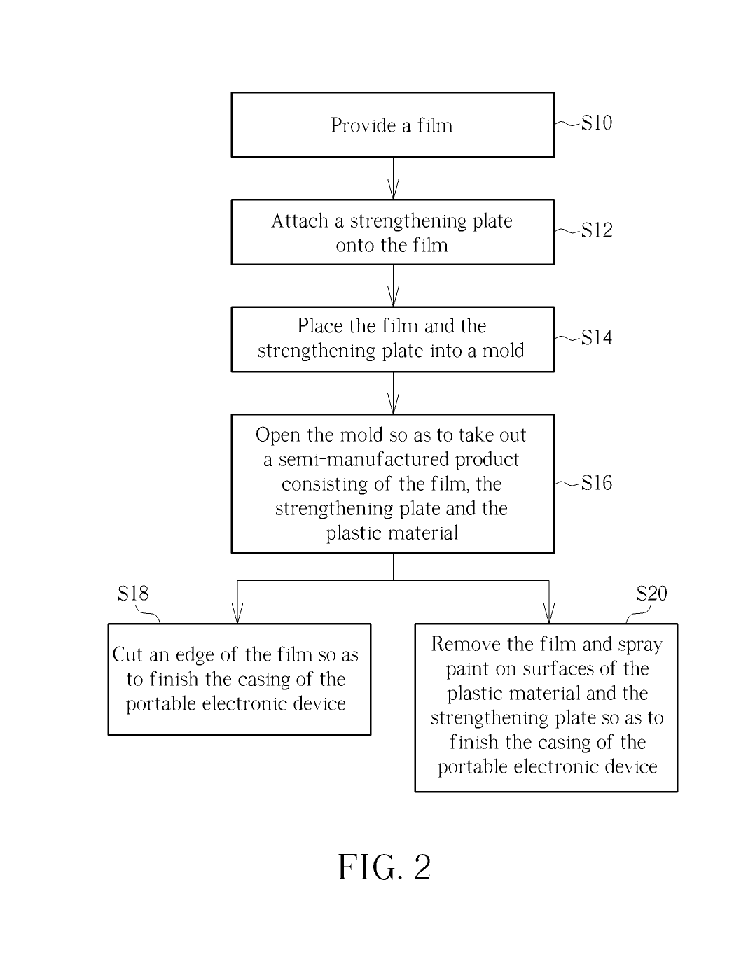

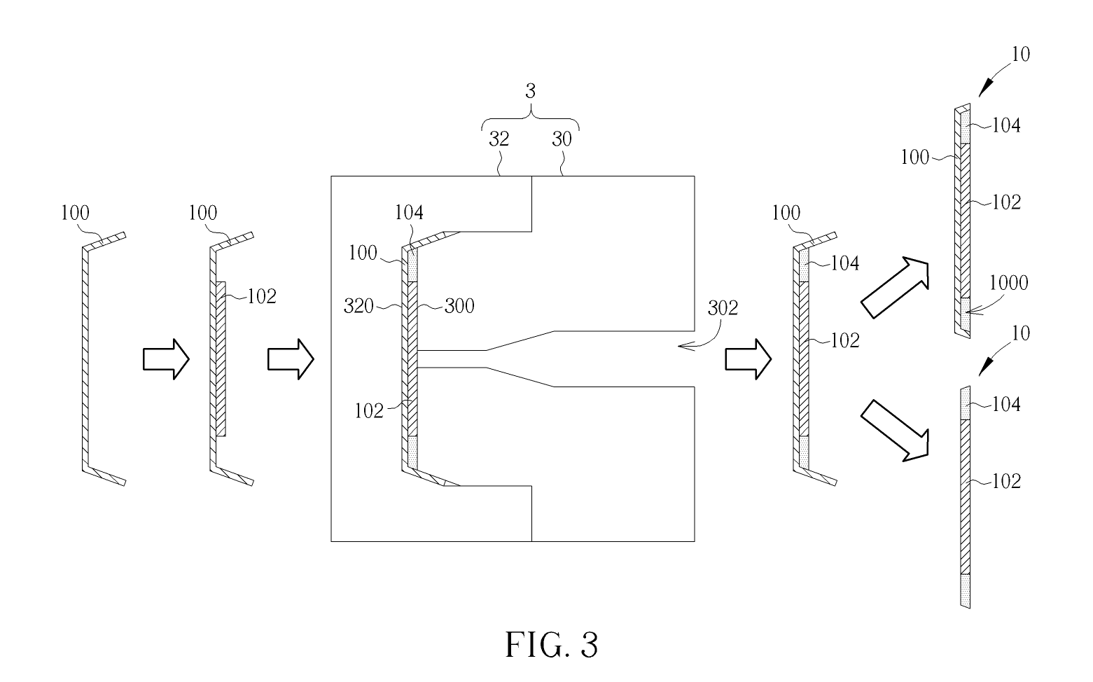

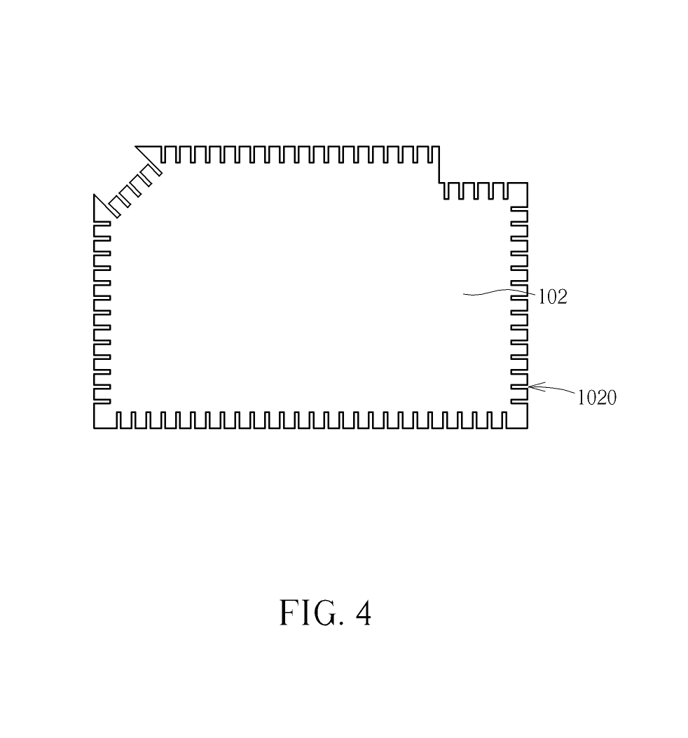

Referring to FIGS. 1 to 4, FIG. 1 is a schematic diagram illustrating a portable electronic device 1 according to an embodiment of the invention, FIG. 2 is a flowchart illustrating a method for manufacturing a casing according to an embodiment of the invention, FIG. 3 is a schematic diagram illustrating processes for FIG. 1, and FIG. 4 is a top view illustrating the strengthening plate 102 shown in FIG. 3. The method shown in FIG. 2 is used for manufacturing a casing 10 of the portable electronic device 1 shown in FIG. 1. In this embodiment, the portable electronic device 1 may be, but not limited to, a notebook. In another embodiment, the portable electronic device 1 may be a tablet personal computer or other electronic devices.

In this embodiment, the casing 10 of the portable electronic device 1 is manufactured using a mold 3 by insert molding. To manufacture the casing 10 of the portable electronic device 1, first of all, step S10 is performed to provide a film 100. In this embodiment, the film 100 may be made of, but not limited to, polyethylene terephthalate (PET), polycarbonate (PC) or poly(methyl methacrylate) (PMMA). Afterward, step S12 is performed to attach a strengthening plate 102 onto the film 100. In this embodiment, the strengthening plate 102 may be made of, but not limited to, carbon fabric or metal (e.g. iron). It should be noted that the strengthening plate 102 can be adhered onto the film 100 by an adhesive while attaching the strengthening plate 102 onto the film 100 and then the adhesive is baked so as to attach the strengthening plate 102 onto the film 100 tightly. The aforesaid adhesive may be, but not limited to, 2K adhesive containing hardening agent.

Then, step S14 is performed to place the film 100 and the strengthening plate 102 into a mold 3. As shown in FIG. 3, the mold 3 comprises a male mold 30 and a female mold 32. In this embodiment, the film 100 is attached on a surface 320 of the female mold 32 and the strengthening plate 102 faces a surface 300 of the male mold 30. Then, a plastic material 104 is injected into the mold 3 through an inlet 302 of the male mold 30 such that the plastic material 104 and the strengthening plate 102 are combined with each other. In this embodiment, the plastic material 104 may be, but not limited to, a mixture of polyamide fiber (PA) and glass fiber (GF), a mixture of polycarbonate (PC) and acrylonitrile-butadiene-styrene (ABS) or a mixture of polyphenylene sulfide (PPS) and glass fiber (GF). It should be noted that a plurality of indentations 1020 may be formed on a periphery of the strengthening plate 102 (as shown in FIG. 4) so as to strengthen the connection between the plastic material 104 and the strengthening plate 102.

Then, step S16 is performed to open the mold 3 so as to take out a semi-manufactured product consisting of the film 100, the strengthening plate 102 and the plastic material 104. After taking the semi-manufactured product out, step S18 may be performed to cut an edge of the film 100 so as to finish the casing 10 of the portable electronic device 1, as shown in FIG. 3. On the other hand, after taking the semi-manufactured product out, step S20 may be performed to remove the film 100 and spray paint on surfaces of the plastic material 104 and the strengthening plate 102 so as to finish the casing 10 of the portable electronic device 1, as shown in FIG. 3. After insert molding, the film 100 can prevent a drop height between an outer surface of the plastic material 104 and the strengthening plate 102 effectively since the film 100 is attached on the outer surface of the plastic material 104 and the strengthening plate 102. Accordingly, no matter whether the film 100 is removed, the surface of the casing 10 is very flat and does not need additional surface treatment (e.g. spackle or grinding by abrasive paper). Furthermore, if the film 100 has to be removed, the strengthening plate 102 may be adhered to the film 100 by an adhesive with low stickiness.

It should be noted that if the film 100 is kept on the casing 10, the casing 10 comprises the film 100, the strengthening plate 102 and the plastic material 104 correspondingly. As shown in FIG. 3, the film 100 has a recess 1000, and the strengthening plate 102 and the plastic material 104 are disposed in the recess 1000 and combined with each other.

Three embodiments in the following are used for describing related parameters set by the invention.

### Embodiment 1

The invention can take a mixture of PA and 45% GF to be the aforesaid plastic material 104, take carbon fabric to make the aforesaid strengthening plate 102, and take PET to make the aforesaid film 100. In this embodiment, the temperature of the plastic material 104 may be between 310° C. and 330° C., the temperature of the male mold 30 and the female mold 32 may be about 130° C., the speed for injecting the plastic material 104 may be between 30% and 40%, and the temperature and time for baking the strengthening plate 102 and the film 100 may be about 60° C. and 30 minutes, respectively.

### Embodiment 2

The invention can take a mixture of PC and ABS to be the aforesaid plastic material 104, take carbon fabric to make the aforesaid strengthening plate 102, and take PET to make the aforesaid film 100. In this embodiment, the temperature of the plastic material 104 may be between 250° C. and 260° C., the temperature of the male mold 30 and the female mold 32 may be about 70° C., the speed for injecting the plastic material 104 may be between 30% and 40%, and the temperature and time for baking the strengthening plate 102 and the film 100 may be about 60° C. and 30 minutes, respectively.

### Embodiment 3

The invention can take a mixture of PPS and 45% GF to be the aforesaid plastic material 104, take carbon fabric to make the aforesaid strengthening plate 102, and take PET to make the aforesaid film 100. In this embodiment, the temperature of the plastic material 104 may be between 310° C. and 330° C., the temperature of the male mold 30 and the female mold 32 may be about 130° C., the speed for injecting the plastic material 104 may be between 30% and 40%, and the temperature and time for baking the strengthening plate 102 and the film 100 may be about 60° C. and 30 minutes, respectively.

It should be noted that the material of the film 100 can be selected according to the plastic material 104. For example, a film capable of resisting high temperature is selected for a high temperature plastic material and a film capable of resisting low temperature is selected for a low temperature plastic material. Furthermore, the parameters adapted for insert molding can be set according to the material of the film 100, the material of the strengthening plate 102 and the plastic material 104.

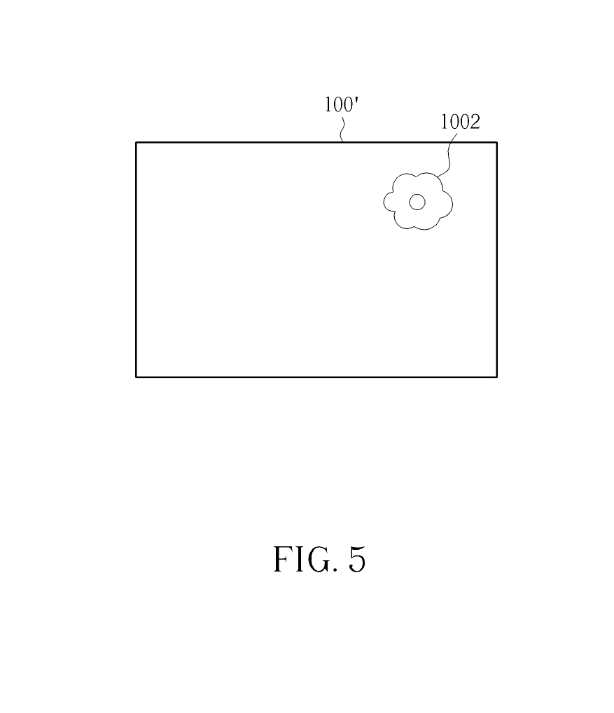

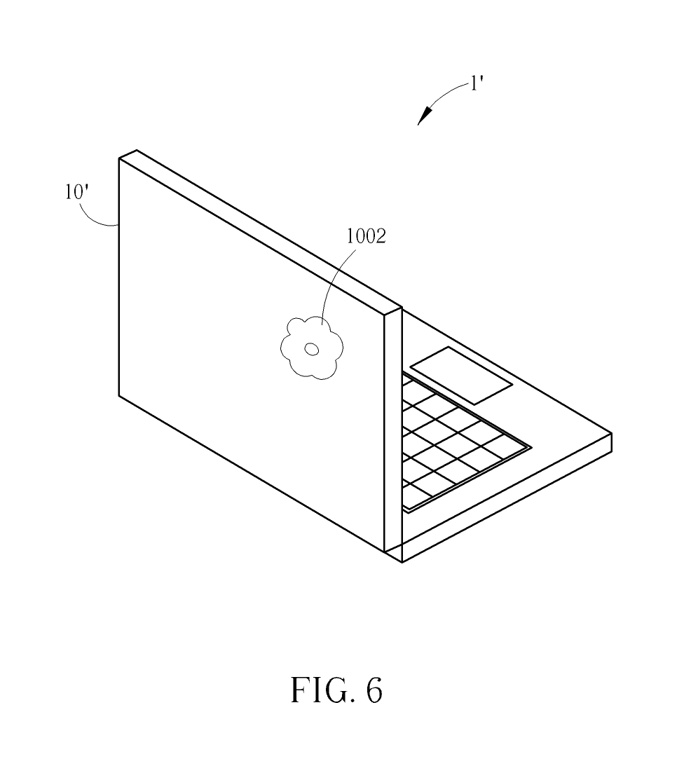

Referring to FIGS. 5 and 6, FIG. 5 is a top view illustrating a film 100′ according to another embodiment of the invention, and FIG. 6 is a schematic diagram illustrating a portable electronic device 1′ according to another embodiment of the invention. As shown in FIGS. 5 and 6, the invention can form a pattern 1002 on a film 100′ in advance such that the pattern 1002 will be formed on a casing 10′ after the plastic material 104 and the strengthening plate 102 are combined with each other. Accordingly, the invention can enhance visual effect of the appearance of the casing 10′ of the portable electronic device 1′. In this embodiment, the pattern 1002 may be formed on the film 100′ by, but not limited to, ink printing, coating or the like.

As mentioned in the above, the invention attaches the strengthening plate onto the film first, places the film and the strengthening plate into the mold together, and then injects the plastic material into the mold such that the plastic material and the strengthening plate are combined with each other. After insert molding, the film can prevent a drop height from being formed on an outer surface of the plastic material and the strengthening plate effectively since the film is attached on the outer surface of the plastic material and the strengthening plate. In other words, after manufacturing the casing of the portable electronic device of the invention by insert molding, the invention can spray paint on the surface of the casing or process the surface of the casing with other appearance treatments directly without additional surface treatment (e.g. spackle or grinding by abrasive paper). Therefore, the invention can save lots of labor and time from surface treatment so as to reduce the manufacture cost.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for manufacturing a casing comprising:
providing a film;
attaching a strengthening plate onto the film;
placing the film and the strengthening plate into a mold; and
injecting a plastic material into the mold such that the plastic material and the strengthening plate are combined with each other.

2. The method of claim 1, further comprising:
cutting an edge of the film.

3. The method of claim 1, further comprising:
removing the film; and
spraying paint on surfaces of the plastic material and the strengthening plate.

4. The method of claim 2, wherein providing a film further comprises:
forming a pattern on the film such that the pattern is formed on the casing after the plastic material and the strengthening plate are combined with each other.

5. The method of claim 3, wherein attaching a strengthening plate onto the film further comprises:
adhering the strengthening plate onto the film by an adhesive; and
baking the adhesive.

6. The method of claim 1, wherein the film is made of polyethylene terephthalate, polycarbonate or poly(methyl methacrylate).

7. The method of claim 1, wherein the strengthening plate is made of carbon fabric or metal.

8. The method of claim 1, wherein the plastic material is one selected from a group consisting of a mixture of polyamide fiber and glass fiber, a mixture of polycarbonate and acrylonitrile-butadiene-styrene, and a mixture of polyphenylene sulfide and glass fiber.

9. A casing of a portable electronic device comprising:
a film having a recess;
a strengthening plate disposed in the recess; and
a plastic material disposed in the recess and combined with the strengthening plate.

10. The casing of claim 9, further comprising a pattern formed on the film.

11. The casing of claim 9, wherein the film is made of polyethylene terephthalate, polycarbonate or poly(methyl methacrylate).

12. The casing of claim 9, wherein the strengthening plate is made of carbon fabric or metal.

13. The casing of claim 9, wherein the plastic material is one selected from a group consisting of a mixture of polyamide fiber and glass fiber, a mixture of polycarbonate and acrylonitrile-butadiene-styrene, and a mixture of polyphenylene sulfide and glass fiber.

14. The casing of claim 9, wherein a plurality of indentations is formed on a periphery of the strengthening plate.
